(19) United States
(12) Patent Application Publication
(10) Pub. No.: US 2013/0104800 A1
(43) Pub. Date: May 2, 2013

(54) FILM-FORMING METHOD AND FILM-FORMING APPARATUS

(71) Applicant: NuFlare Technology, Inc, Numazu-Shi (JP)

(72) Inventors: Kunihiko SUZUKI, Shizuoka (JP); Yuusuke SATO, Tokyo (JP); Yoshikazu MORIYAMA, Shizuoka (JP)

(73) Assignee: NuFlare Technology, Inc, Numazu-Shi (JP)

(21) Appl. No.: 13/661,362

(22) Filed: Oct. 26, 2012

(30) Foreign Application Priority Data
Oct. 31, 2011 (JP) 2011-238285

(51) Int. Cl. C30B 25/14; C23C 16/458; C30B 25/12

(52) U.S. Cl. 117/98; 118/730

(57) ABSTRACT

A film-forming method and apparatus for performing vapor phase growth reaction avoiding a substrate becoming adhered to a substrate supporting portion, comprising:

placing a substrate on a substrate supporting portion in a film-forming chamber, supplying a source gas into the film-forming chamber while the substrate is rotating on a cylindrical portion for supporting the substrate supporting portion thereon, supplying a purge gas into the cylindrical portion and forming a film on the substrate while at least a part of the substrate is vibrating up and down on the substrate supporting portion by discharge of the purge gas from between the substrate and the substrate supporting portion. The vibration allowing the substrate to not become adhered to the substrate supporting portion, and thus increase throughput of the operation.

### CROSS-REFERENCE TO THE RELATED APPLICATION

The entire disclosure of the Japanese Patent Applications No. 2011-238285, filed on Oct. 31, 2011 including specification, claims, drawings, and summary, on which the Convention priority of the present application is based, are incorporated herein in its entirety.

### FIELD OF THE INVENTION

The present invention relates to a film-forming method and a film-forming apparatus.

### BACKGROUND ART

Epitaxial growth technique for used depositing a monocrystalline film on a substrate such as a wafer is conventionally used to produce a semiconductor device such as a power device (e.g., IGBT (Insulated Gate Bipolar Transistor)) requiring a relatively thick crystalline film.

In the case of film-forming apparatus used in an epitaxial growth technique, a wafer is placed inside a film-forming chamber maintained at an atmospheric pressure or a reduced pressure, and a source gas is supplied into the film-forming chamber while the wafer is heated. As a result of this process, a pyrolytic reaction or a hydrogen reduction reaction of the source gas occurs on the surface of the wafer so that an epitaxial film is formed on the wafer.

In order to produce a thick epitaxial film in high yield, a fresh source gas needs to be continuously brought into contact with the surface of a grown on a wafer while the wafer is rotated uniformly heated substrate to increase a film-forming rate. Therefore, in the case of a conventional film-forming apparatus, a film is epitaxially at a high speed (see, for example, Japanese Patent Application Laid-Open No. H05-152207).

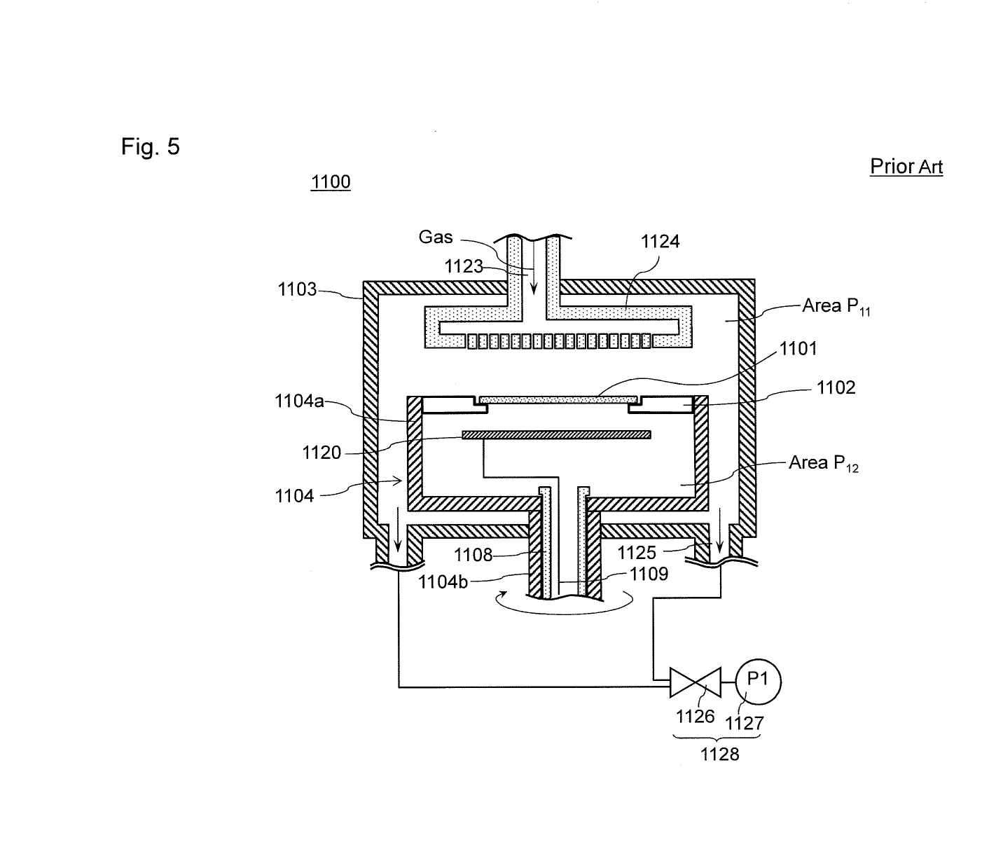

FIG. 5 is a schematic cross-sectional view of a conventional film-forming apparatus.

A conventional film-forming apparatus 1100 includes a chamber 1103 used as a film-forming chamber for forming an epitaxial film on a wafer 1101 as a semiconductor substrate by vapor phase growth reaction. A gas supply portion 1123 used for supplying a source gas for growing the crystalline film on the surface of the heated wafer 1101 is provided in the upper part of the chamber 1103. The gas supply portion 1123 is connected with a shower plate 1124 on which has a plurality of through-holes for the source gas.

A plurality of gas discharge portions 1125 that discharge the source gas subjected to reaction, are provided in the bottom of the chamber 1103. The gas discharge portions 1125 are connected with a discharge system 1128 comprising of an adjustment valve 1126 and a vacuum pump 1127. A ring-shaped susceptor 1102 for holding the wafer 1101 is provided above a rotating portion 1104 in the chamber 1103. The susceptor 1102 has a counterbore provided thereon so that the outer periphery of the wafer 1101 can be positioned in the counterbore.

The rotating portion 1104 has a cylindrical portion 1104a and a rotating shaft 1104b. The rotating shaft 1104b rotates, and then the susceptor 1102 will be rotated via the cylindrical portion 1104a.

As seen in FIG. 5, the cylindrical portion 1104a includes an opening in the upper part of the portion. The susceptor 1102 is positioned in the opening of the cylindrical portion 1104a; the wafer 1101 is placed on the susceptor 1102. As the opening is covered with the susceptor 1102 and the wafer 1101 a hollow area (herein after area P₁₂) is formed that is separated from the area P₁₁ in the chamber 1103.

A heater 1120 is provided in area P₁₂. Electricity is conducted to the heater 1120 via wires 1109 in a cylindrical shaped shaft 1108 within the rotating shaft 1104b, as a result the back surface of the wafer 1101 is heated by the heater 1120.

The rotating shaft 1104b of the rotating portion 1104 is connected with the rotating system (not shown) positioned outside of the chamber 1103. The cylindrical portion 1104a is rotated, as a result the susceptor 1102 is rotated via the cylindrical portion 1104a, and the wafer 1101 is rotated with the susceptor 1102.

A transfer robot (not shown) is used for transferring the wafer 1101 into, or out of the chamber 1103 as seen in FIG. 5. In this case, a substrate rising means (not shown) is used for moving the wafer 1101 up and down. When the wafer 1101 is transferred out of the chamber 1103, for example, the wafer 1101 is moved in an upwards direction via the substrate rising means to take it away from the susceptor 1102. The wafer 1101 is then transferred to the transfer robot, and then the wafer 1101 is transferred out of the chamber 1103. When the wafer 1101 is transferred into the chamber 1103, the wafer 1101 is transferred from the transfer robot to the substrate rising means, and then the wafer 1101 is lowered via the substrate rising means by the elevator to be placed on the susceptor 1102.

In the conventional film-forming apparatus 1100 as seen in FIG. 5, when vapor phase growth reaction is performed in the chamber 1103 thin film created by the source gas is formed not only on the wafer 1101 but also on the susceptor 1102 supporting the wafer 1101. If vapor phase growth reaction is performed on another wafer 1101 newly transferred into the chamber 1103, a new thin film tends to be produced on the former thin film, as this process continues the wafer 1101 can become stuck to the susceptor 1102.

If the wafer 1101 becomes stuck to the susceptor 1102, it becomes difficult to move the wafer 1101 away from the susceptor 1102 and transfer the wafer 1101 out from the chamber 1103. As a result, the adhesion between the wafer 1101 and the susceptor 1102 causes a decrease in the speed of forming epitaxial film on the wafer 1101.

The present invention has been made to address the above issues. That is, an object of the present invention is to provide a film-forming apparatus and a film-forming method, the purpose of which can prevent adhesion between a substrate such as the wafer and the susceptor that the substrate is placed upon.

Other challenges and advantages of the present invention are apparent from the following description.

### SUMMARY OF THE INVENTION

In a first embodiment of this invention, a film-forming method comprising: placing a substrate on a susceptor in a film-forming chamber, supplying a source gas into the film-forming chamber while the substrate is rotating on a cylindrical portion for supporting the susceptor thereon, supplying a purge gas into the cylindrical portion and forming a film on the substrate while at least a part of the substrate is vibrating up and down on the susceptor by discharge of the purge gas from between the substrate and the susceptor.

In a second embodiment of this invention, a film-forming apparatus comprising: a film-forming chamber, a source gas supply portion for supplying a source gas into the film-forming chamber, a susceptor for holding a substrate in the film-forming chamber, a rotating portion having a cylindrical portion for supporting the susceptor, a purge gas supply portion for supplying the purge gas into the cylindrical portion, and a control unit for controlling the supply of the source gas and the purge gas so that the purge gas is discharged from between the substrate and the susceptor, thereby at least a part of the substrate rises on the susceptor.

### BRIEF DESCRIPTION OF THE DIAGRAMS

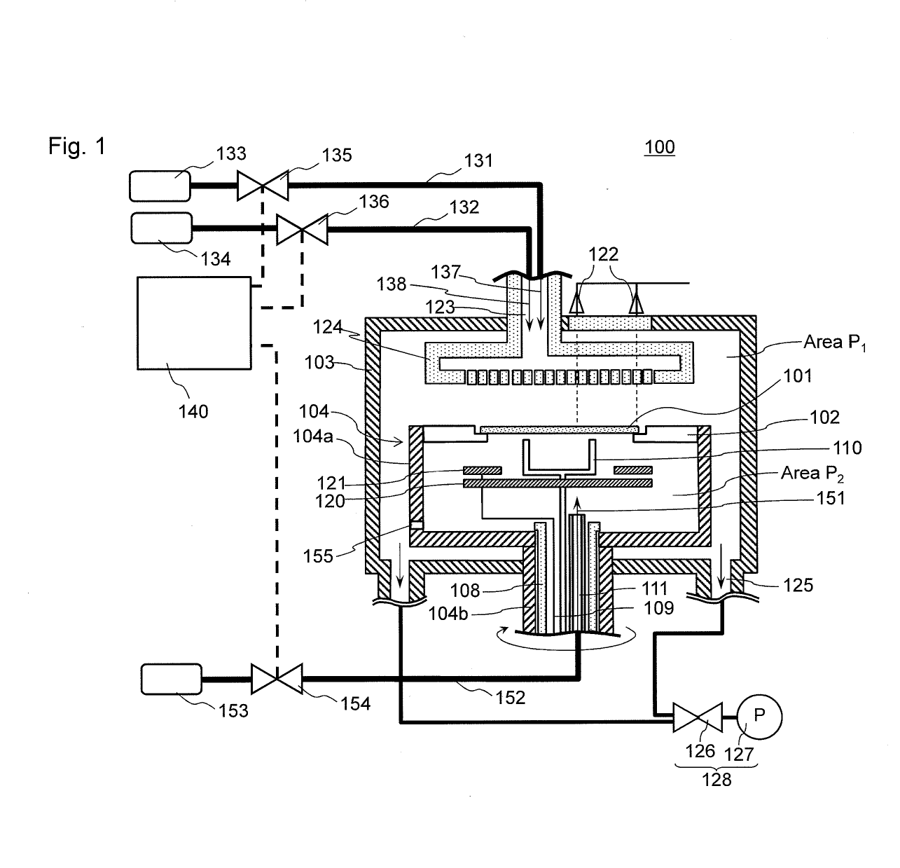

FIG. 1 is a schematic cross-sectional view of a single wafer film-forming apparatus according to the present embodiment.

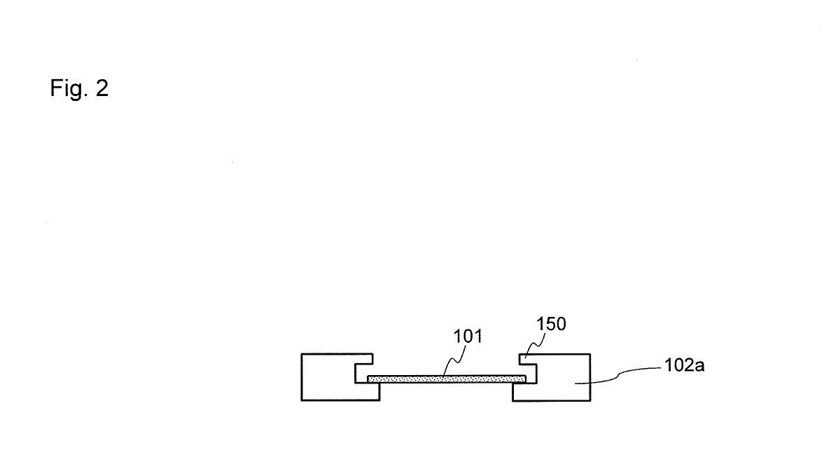

FIG. 2 is a schematic cross-sectional view of a susceptor of a film-forming apparatus according to the present embodiment.

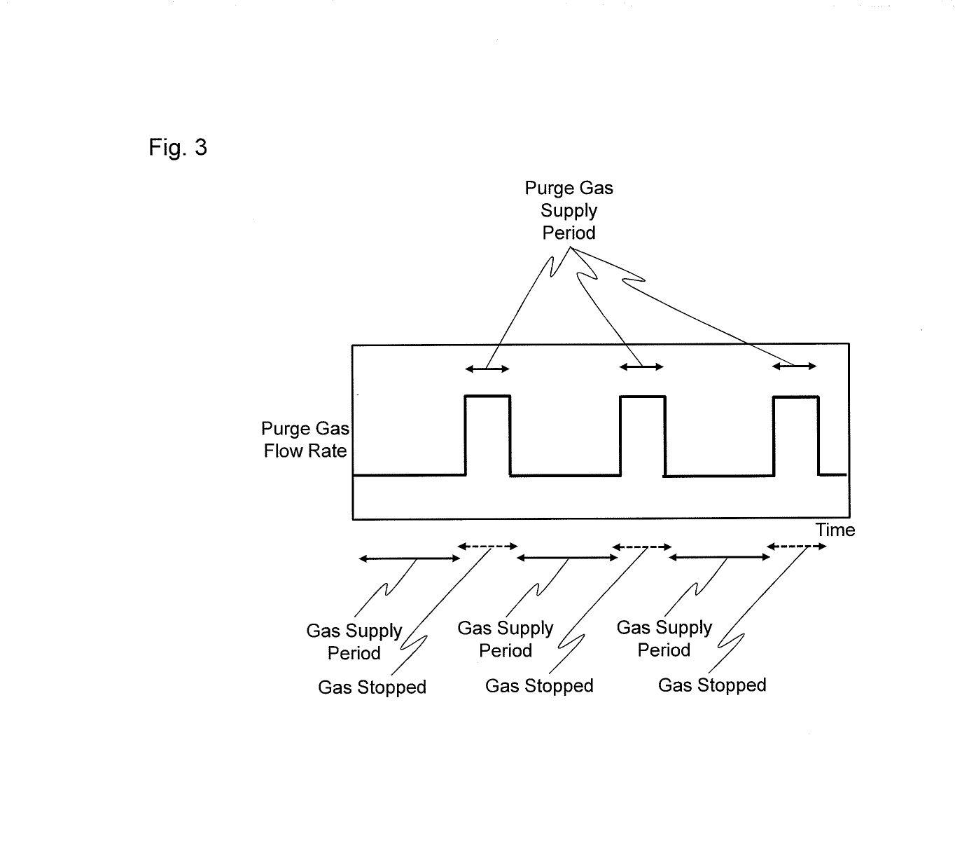

FIG. 3 shows an example of the film-forming method according to the present embodiment.

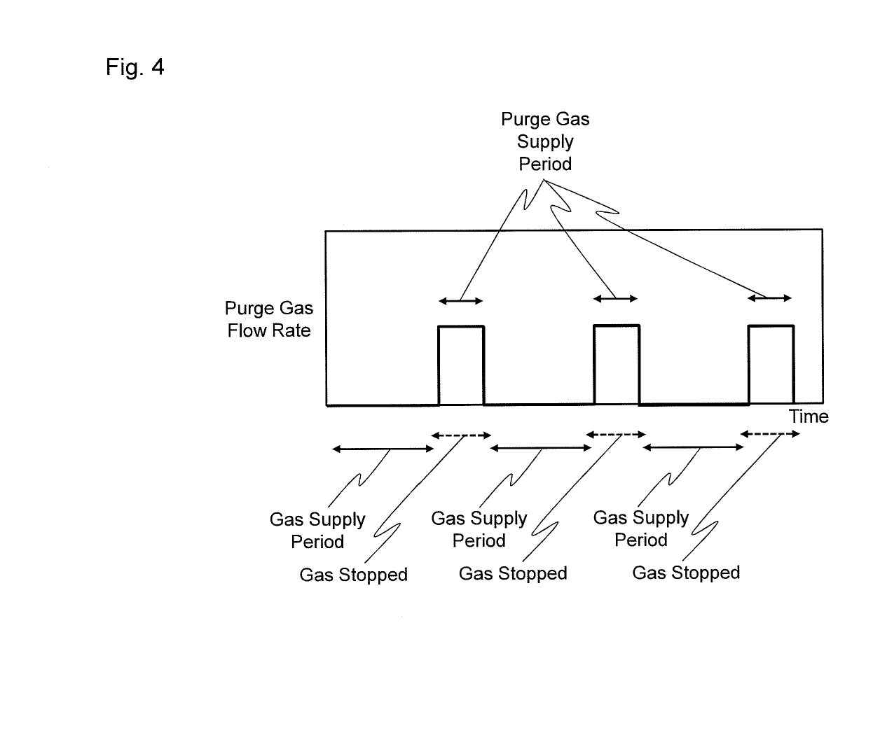

FIG. 4 shows another example of the film-forming method according to the present embodiment.

FIG. 5 is a schematic cross-sectional view of a conventional film-forming apparatus.

### DETAILED DESCRIPTION OF THE INVENTION

### Embodiment 1

FIG. 1 is a schematic cross-sectional view of a single wafer film-forming apparatus according to the present embodiment.

FIG. 1 is a schematic cross section of a film-forming apparatus according to the present embodiment.

In the present embodiment, a substrate 101 may be a wafer, as one example of a substrate, is used to form a film thereon. The substrate 101 is placed on the susceptor 102 of the film-forming apparatus 100 according to the present embodiment as shown in FIG. 1.

The film-forming apparatus 100 includes a chamber 103 to be used for forming an epitaxial film on the substrate 101 via vapor phase growth reaction.

A gas supply portion 123, used for supplying a source gas is provided at the upper of the chamber 103 of the film-forming apparatus 100. Gas pipes 131 and 132 are connected to the gas supply portion 123. The other end of the gas pipes 131 and 132 are connected to gas storing portions 133 and 134 comprising of, for example, a gas cylinder. Gas valves 135, 136 for adjusting the supply of the gas, are connected along the gas pipe 131, 132. The source gas 137 for forming the epitaxial film on the substrate 101 is stored in the gas storing portion 133. The carrier gas 138 is stored in the gas storing portion 134. The gas valve 135 is provided to control the supply of the source gas 137 that is supplied from the gas supply portion 123 to the chamber 103. The gas valve 136 is provided to control the supply of the carrier gas 138 that is supplied from the gas supply portion 123 to the chamber 103.

The film-forming apparatus 100 includes a gas control unit 140 for controlling the supply of the gas that is supplied to the chamber 103. The gas control unit 140 is connected with the gas valves 135, 136. The gas control unit 140 controls the gas valves 135, 136, and thereby controls the supply of the source gas 137 and the carrier gas 138 that are supplied from the gas supply portion 123 to the chamber 103. The source gas 137 for forming the epitaxial film is supplied on the surface of the substrate 101 that is heated to a high temperature.

The gas supply portion 123 is connected with a shower plate 124 on which has a plurality of through-holes for the source gas 137 etc. The shower plate 124 is provided at the upper portion of the chamber 103 so that it faces the surface of the substrate 101, thereby the source gas 137 can be supplied to the surface of the substrate 101.

A plurality of gas discharge portions 125 for discharging the source gas 137, carrier gas 138, and other gases resulting from the epitaxial reaction, are provided at the bottom of the chamber 103. The gas discharge portions 125 are connected to a discharge system 128 comprising an adjustment valve 126 and a vacuum pump 127. The discharge system 128 is controlled by a control system (not shown) to adjust the pressure in the chamber 103.

A susceptor 102 is provided above the rotating portion 104 in the chamber 103. The susceptor 102 is a ring-shape with a counterbore provided within the opening so that the outer periphery of the substrate 101 can be positioned in the counterbore. As the susceptor 102 is used under high temperatures, a susceptor obtained by coating the surface of isotropic graphite with SiC, of a high degree of purity and a high resistance to heat, by CVD (Chemical Vapor Deposition) is used (as one example).

The shape of the susceptor 102 is not limited to the example of FIG. 1.

FIG. 2 is a schematic cross-sectional view of another susceptor in a film-forming apparatus according to the present embodiment.

Another example of a susceptor 102, as seen in 102a, has an overhanging portion 150 that overhangs the counterbore of the susceptor 102a. The overhanging portion 150 is provided to control the up-and-down motion of the substrate 101 on the susceptor 102a so that the substrate 101 doesn't come out of the susceptor 102a while the substrate 101 is rotating.

The rotating portion 104 includes a cylindrical portion 104a and a rotating shaft 104b. The susceptor 102 is held above the cylindrical portion 104a in the rotating portion 104. A motor (not shown) rotates the rotating shaft 104b resulting in the susceptor 102 rotating via the cylindrical portion 104a. Accordingly the substrate 101 can be rotated after the substrate 101 is placed on the susceptor 102.

As seen in FIG. 1, the cylindrical portion 104a has an opening in the upper part of the portion. The susceptor 102 can be positioned in the opening, or on the opening of the cylindrical portion 104a, and then the substrate 101 is placed on the susceptor 102. This results in the opening being covered with the susceptor 102 and the substrate 101, and a hollow area (herein after area P₂) is formed. Inside the chamber 103 the area P₂ is substantially separated from area P₁ by the substrate 101 and the susceptor 102.

Therefore, it is possible to prevent contamination of the substrate 101 by a contaminant generated around an in-heater 120 and an out-heater 121 (described later). It is also possible to prevent the source gas 137, and the carrier gas 138 in the area P₁, from coming into the area P₂ and contacting with the in-heater 120 and the out-heater 121.

In the film-forming apparatus 100 according to the present embodiment, the top portion of a gas supply pipe 111 is positioned in the area P₂. A purge gas 151 is supplied to the area P₂ by the gas supply pipe 111.

In the film-forming apparatus 100, a through-hole can be provided at the sidewall around the bottom of the cylindrical portion 104a so that the through-hole is bored through the sidewall, as shown in FIG. 1. The through-hole is a discharge portion 155 which discharges the purge gas 151 supplied to the area P₂. The purge gas 151 is supplied to the area P₂ according to the amount that can be discharged from the discharge portion 155 in the cylindrical portion 104a, thereby the purge gas 151 can purge around the in-heater 120 and the out-heater 121. In this case, the purge gas 151 that was supplied to the area P₂ will be discharged from the discharge portion 155 and the state of separation of the area P₂ from the area P₁ can be substantially maintained.

The in-heater 120 and the out-heater 121 used as heaters are provided in the area P₂. For use as the in-heater 120 and the out-heater 121, resistive heaters can be used; the material of these are obtained by coating the surface of carbon material with SiC of a high resistance to heat. Electricity is conducted to these heaters via wires 109 positioned in a cylindrical shaped shaft 108, wherein the cylindrical shaped shaft 108 consists of quartz, contained in the rotating shaft 104b; thereby these heaters heat the back surface of the wafer 101 placed on the susceptor 102. The out-heater 121 mainly heats the periphery of the substrate 101, as the heat in the outer periphery of the substrate 101 easily escapes. The out-heater 121 is provided as well as the in-heater 120, and the substrate 101 can be uniformly heated by the double heaters.

The surface temperature of the substrate 101 is measured by radiation thermometers 122 provided at upper portion of the chamber 103. It is preferred that the shower plate 124 be formed of quartz, because the use of quartz prevents the shower plate 124 affecting the temperature measurement of the radiation thermometers 122. The measured data of the temperature is sent to a control system (not shown), and then the control system provides feedback to an output control system of the in-heater 120 and the out-heater 121. Accordingly the substrate 101 can be heated to the desired temperature.

A pin 110, capable of moving in an up and down direction, supporting the substrate 101, is provided in the shaft 108. The end of the pin 110 extends to a substrate rising means (not shown) provided at the bottom of the shaft 108. The pin 110 can be moved up and down by the substrate rising means. The pin 110 is used when the substrate 101 is transferred into and out of the chamber 103. The pin 101 supports the bottom of the substrate 101, and then rises to move the substrate 101 away from the susceptor 102. The substrate 101 is then positioned above the rotating portion 104 separate from the susceptor 102 by the pin 110, allowing a transfer robot (not shown) to remove the substrate 101.

A gas supply pipe 111 is provided in the shaft 108. The opening of the gas supply pipe 111 extends into the area P₂ inside of the cylindrical portion 104a. A purge gas 151 is supplied to the area P₂ by the gas supply pipe 111. The gas supply pipe ill is connected with a gas pipe 152. The end of the gas pipe 152 is connected with a gas-storing portion 153 comprising of a gas cylinder. The purge gas 151 supplied to the area P₂ is stored in the gas-storing portion 153.

A gas valve 154 for adjusting the supply of the gas is connected to the gas pipe 152. The gas valve 154 is connected with the above-mentioned gas control unit 140. Therefore the gas control unit 140 controls the gas valve 154, and thereby the purge gas 151, which is supplied from the gas pipe 111 to the area P₂, is controlled in the film-forming apparatus 100. The gas control unit 140 also controls the source gas 137 for forming the epitaxial film on the surface of the substrate 101, the carrier gas 138, and the purge gas 151, which is supplied to purge the area P₂.

The purge gas 151 stored in the gas storing portion 153, to be supplied from the gas supply pipe 111 to the area P₂ by the gas control unit 140, is at least one selected from the group consisting of an inert gas such as argon (Ar) gas and helium (He) gas, hydrogen (H₂) gas and nitrogen (H₂) gas.

In the film-forming apparatus 100 according to the present embodiment, the source gas 137 that will be supplied to the area P₁ and the purge gas 151 for purging the area P₂ are individually controlled by the gas control unit 140, in the film-forming process for forming the epitaxial film on the substrate 101. The purge gas 151 can also be supplied with the source gas 137 in the film-forming apparatus 100.

In the film-forming apparatus 100, the purge gas 151 can be supplied to the area P₂ of the cylindrical portion 104a while the substrate 101 on the susceptor 102 is rotating. The purge gas 151 supplied the area P₂ is exhausted from between the substrate 101 and the susceptor 102, thereby at least a part of the substrate 101 will rise on the susceptor 102. That is, the epitaxial film is formed using the source gas 137 supplied in the Area P₁ on the substrate 101 while at least a part of the substrate 101 is rising on the susceptor 102 in the film-forming apparatus 100.

In the film-forming apparatus 100, the purge gas 151 is supplied to area P₂ of the cylindrical portion 104a; thereby at least a part of the rotating substrate 101 will rise on the susceptor 102. The discharge portion 155 can be provided in the film-forming apparatus 100 as mentioned above. The amount of purge gas 151 that can be exhausted from the discharge portion 155 may be supplied into the area P2 and purged around the in-heater 120 and the out-heater 121 before the substrate 101 will rise. In that situation, the amount of the purge gas 151 supplying to the area P₂ can be temporarily increased; thereby at least a part of the substrate 101 can be risen on the susceptor 102.

The film-forming apparatus 100 is constructed so that the pressure in the area P₁ of the chamber 103 is almost same as the pressure of the area P₂ in the cylindrical portion 104a. Moreover the pressure of the area P₂ is a little higher than the pressure the area P₁ so that the source gas 137 in the area P₁ and the carrier gas 138 used with the source gas 137 cannot be enter into the area P₂. For example, the pressure of the area P₁ is set to 300 Torr, the pressure of the area P₂ in the cylindrical portion 104a can set between 301 Torr to 305 Torr. Therefore the flow rate of the purge gas 151 supplied to the area P₂ can be set at a rate of 5 L/minute or below. In the film-forming apparatus 100, such flow rate of the purge gas 151 can be always supplied to the area P₂ in the process that the epitaxial film is formed while the substrate is rotating.

The purge gas 151 is supplied to the area P₂ of the cylindrical portion 104a to make at least a part of the rotating substrate 101 rise on the susceptor 102. In this situation, the supply amount of the purge gas 151 is temporarily increased over the current supply amount by the gas control unit 140. The supply amount of the purge gas 151 is temporarily increased to 10 times or more, for example, 6 L/minute to 10 L/minute to make a least a part of the substrate 101 rise on the susceptor 102.

The substrate 101 can be temporarily raised on the susceptor 102. The substrate 101 will then be back to the previous position on the susceptor 102 by the exhaustion of the purge gas 151 from between the substrate 101 and the susceptor 102. This is repeated; thereby the substrate 101 can move slightly up and down. At the same time the substrate 101 is rotated at high speeds via the susceptor 102. That is, the substrate 101 is rotating at high speeds while slightly moving up and down.

In the film-forming apparatus 100, the epitaxial film can be formed on the substrate 101 while the substrate 101 is rotating and vibrating up and down on the susceptor 102. At that time, the outer periphery of the wafer 101 that is positioned in the counterbore, occasionally contacts the counterbore, therefore the epitaxial film will not be formed on the outer periphery.

As mentioned above, the thin film caused by the source gas 137 is formed not only on the surface of the substrate 101 but also on the surface of the susceptor 102 supporting the substrate 101 when the vapor phase growth reaction is performed in the chamber 103 of the film-forming apparatus 100. There is a concern that the substrate will become attached to the susceptor via the thin film on the susceptor in the above-mentioned conventional film-forming apparatus.

However, if the substrate 101 can be rotated at high speeds while vibrating up and down on the susceptor 102 as a result of the purge gas 151 supplied to the area P₂ of the cylindrical portion 104a in the film-forming apparatus 100 according to the present embodiment, the adhesion between the substrate 101 and the susceptor 102 can be prevented, even if a thin film caused by the source gas 137 is formed between the substrate 101 and the susceptor 102.

### Embodiment 2

Next, the film-forming method according to the present embodiment will be described. The film-forming apparatus 100 as shown in FIG. 1 can perform the film-forming method according to the present embodiment. This will be explained with reference to FIG. 1.

In the film-forming method according to the present embodiment, an epitaxial film is formed on the substrate 101 by vapor phase growth reaction. The adhesion between the substrate 101 and the susceptor 102 can be prevented even if a thin film, caused by the source gas 137, is formed between the substrate 101 and the susceptor 102. The diameter of the substrate 101 is 200 mm or 300 mm for example.

The substrate 101 is transferred into the chamber 103 of the film-forming apparatus 100 by a transfer robot (not sown). The purge gas 151 can be supplied to the area P₂ via the gas supply pipe 111, which extends into the area P₂, by the gas control unit 140 when the substrate 101 is transferred. The flow rate of the purge gas 151 is determined so that the substrate 101 can be positioned on the susceptor 102. That is, the flow rate is preferably determined so that at least a part of the substrate 101 will not rise on the susceptor 102 by the exhaustion of the purge gas 151 supplied to the area P₂ from between the substrate 101 and the susceptor 102. For example, the flow rate of the purge gas 151 supplied to the area P₂ is determined at a rate of 5 L/minute or below.

The previously mentioned gas can be used as the purge gas 151. Further the purge gas 151 is preferably chosen from at least one of argon gas and nitrogen gas that will avoid damaging the in-heater 120 and the out-heater 121 consisting of carbon material if the purge contacts these heaters.

A pin 110 capable of moving in an up and down direction supporting the substrate 101, is provided through the rotating shaft 104b in the rotating portion 104 of the film-forming apparatus 100 as shown in FIG. 1. The substrate 101 is transferred to the pin 110 from the transfer robot.

The pin 110 rises from the first position to a predetermined position above the susceptor 102 to receive the substrate 101 from the transfer robot, after the substrate 101 is transferred to the pin 110, the pin 110 descends while the substrate is held by the pin 110.

The pin 110 is returned to the first position as shown in FIG. 1. Thereby the substrate 101 is positioned on the susceptor 102 on the cylindrical portion 104a of the rotating portion 104.

Next, the pressure of the chamber 103 is set to a specific atmospheric pressure or a reduced pressure, and then hydrogen gas as a carrier gas 138 is supplied from the gas supply portion 123 to the area P₁ by the gas control unit 140. The substrate 101 is rotates at about 50 rpm via the rotating portion 104 while the carrier gas 138 is flows.

The purge gas 151 having the above-mentioned flow rate, is supplied to the area P₂ of the cylindrical portion 104a. The purge gas 151 is purged in the area P₂, and then is exhausted through the discharge portion 155. The area P₂ is substantially separated from the area P₁.

When the cylindrical portion 104a for forming the area P₂ doesn't have the discharge portion 155, the supply of the purge gas 151 would be stopped or a small amount of the purge gas 151 would be supplied. In this case, the area P₂ can be substantially separated from the area P₁. As a result the substrate 101 can remain stable on the susceptor 102.

Next, the substrate 101 is heated to between 1100 and 1200 degrees by the in-heater 120 and the out-heater 121. For example, the substrate 101 would be gradually heated to 1150 degrees as a film-forming temperature.

After it is confirmed that the temperature of the substrate 101 measured by the radiation thermometer 122 has reached 1150° C., the number of revolutions of the substrate 101 positioned on the susceptor 102 is gradually increased to a predetermined speed. The source gas 137 is supplied through the shower plate 124 from the gas supply portion 123 to the chamber 103 by the gas control unit 140. In the present embodiment, trichlorosilane can be used as a source gas 137. The source gas 137 that is mixed with hydrogen gas as a carrier gas 138, is introduced from the gas supply portion 123 into the area P₁ of the chamber 103.

In the film-forming method according to the present embodiment, the gas control unit 140 starts supplying the source gas 137 from the gas supply portion 123 to the area P₁, and increases the supply amount of the purge gas 151 from the gas supply pipe 111 to the area P₂. Thereby the purge gas 151 can be exhausted through the opening between the substrate 101 and the susceptor 102, and at least a part of the substrate 101 can be risen while the substrate 101 is rotating. That is, the substrate 101 is rotating at high speed while vibrating up and down as mentioned above.

If the purge gas 151 is not supplied through the gas supply pipe 111 to the area P₂ before the source gas 137 is supplied through the gas supply portion 123 to the area P₁, the purge gas 151 is supplied through the gas supply pipe 111 to the area P₂, at the same time that the source gas 137 is supplied to the area P₁. Then, at least a portion of the substrate 101 is rising on the susceptor 102 while it is rotating.

The source gas 137 introduced to the area P₁ in the chamber 103 flows downward toward the substrate 101. The substrate 101 is rotated at high speed while slightly vibrating up and down as a result of the supply of the purge gas 151 to the area P₂ of the cylindrical portion 104a by the gas control unit 140, as mentioned above.

While the temperature of the substrate 101 is maintained at 1150 degrees, and the susceptor 102 on the cylindrical portion 104a is rotating at 900rpm or more, the source gas 137 is continuously supplied to the substrate 101 through the shower plate 124 from the gas supply portion 123.

As a result, the speed of the vapor phase growth reaction process on the substrate 101 is increased, and then the epitaxial film can be efficiently formed at high speed.

According to the present embodiment, the susceptor 102 is rotated while the source gas 137 is been flowing, thereby the silicon epitaxial film can be uniformly formed on the substrate 101. For example, the silicon epitaxial film can have a thickness of 10 μm or more, usually between 10 μm to 100 μm on the substrate having a diameter of 300 mm. The rotation of the substrate is preferable to be fast, for example about 900 rpm as the above-mentioned, to form a thick film during the film-formation.

In the film-forming method according to the present embodiment, when the vapor phase growth reaction is performed in the film-forming chamber 103, a thin film formed by the source gas 137 would be formed not only the surface of the substrate 101 but also on the susceptor 102 supporting the substrate 101 as mentioned above.

The film-forming apparatus 100 of the present embodiment, utilizes the purge gas 151 supplied to the area P₂ of the cylindrical portion 104a by the gas control unit 140. The substrate 101 can be rotated at high speed while slightly vibrating up and down as mentioned above. Accordingly, adhesion between the substrate 101 and the susceptor 102 can be prevented even if a thin film formed by the source gas 137 is formed between the substrate 101 and the susceptor 102.

After the epitaxial film having a predetermined thickness is formed on the substrate 101, the heating by the in-heater 120 and the out-heater 121 is stopped and the supply of the source gas 137 from the gas supply portion 123 is finished. The supply of the carrier gas 138, controlled by the gas control unit 140, can be also stopped along with the source gas 137, or the supply of the carrier gas 138 can continue until the temperature of the substrate 101 reaches, or is below, a predetermined value.

When the source gas 137 is finished being supplied, the increased level of purge gas 151 should finish, however the purge gas 151 should continue at the previous rate into the area P₂.

After the film-formation on the substrate 101 is finished, and the substrate 101 on which the epitaxial film was formed is cooled to the predetermined temperature, the substrate 101 is transferred out of the chamber 103. In this case, the pin 110 is raised. The pin 110 supports the bottom of the substrate 101. The pin 110 is further moved in an upward direction to move the substrate 101 away from the susceptor 102. In the film-forming method according to the present embodiment, the substrate 101 is prevented sticking to the susceptor 102. Therefore, it is easy for the pin 110 to move the substrate 101 with the epitaxial film 102 away from the susceptor 102, and the substrate 101 and the epitaxial film on the substrate 101 will not damaged.

The substrate 101 is transferred to the transfer robot (not shown) by the pin 110. After that, the robot 101 transfers the substrate 101 out of the chamber 103.

In the present embodiment, the gas control unit 140 can increase the amount of purge gas 151 supplied to the area P₂ when the supply of the carrier gas 138 to the area P₂ is started. Moreover the gas control unit 140 can increase the amount of the supply of the purge gas 151 before the supply of the carrier gas 138 to the area P₂ is started. For example, the substrate 101 is rotated at about 50rpm, and then the supply of the purge gas 151 can be increased while the substrate 101 is gradually heated to the film-forming temperature, by the in-heater 120 and the out-heater 121.

In the film-forming method according to the present embodiment, for example, the amount of the purge gas 151 is increased through the gas supply pipe 111 to the area P₂ when the source gas 137 is supplied from the gas supply portion 123 to the area P₁ by the gas control unit 140.

In the film-forming method according to the present embodiment, the time of temporarily increasing the supply of the purge gas 151 does not need to be a continuous period. For example, in another example of the film-forming method according to the present embodiment, a plurality of periods of increasing the amount of the supply of the purge gas 151 can be intermittently set while the epitaxial film is formed on the substrate 101, that has been heated, by the supply of the source gas 137.

In another example of the film-forming method, the period of supplying the purge gas 151 at the amount before increasing can be set between the periods for increasing the supply of the purge gas 151.

According to another example, the period for rotating the substrate, heated at a high temperature, at high speed while it is slightly vibrating up and down can be set while the supply of the purge gas 151 is increasing. Therefore, the adhesion between the substrate 101 and the susceptor 102 can be prevented even if the thin film caused by the source gas 137 is formed between the substrate 101 and the susceptor 102.

In the film-forming method according to the present embodiment, the source gas 137 can be continuously supplied when the substrate 101 is heated to a high temperature and rotated at a high speed to form the epitaxial film on the substrate 101 as mentioned above. The source gas 137 can also be intermittently supplied when the epitaxial film is formed on the substrate 101 that is heated to a high temperature, thereby the speed of film-forming will be higher and the film will be efficiently formed. That is, at least one period for temporarily stopping the supply of the source gas 137 can be set while the source gas 137 is supplied on the substrate 101, heated to a high temperature, to form the epitaxial film. Thereby the saturation of the vapor phase growth reaction on the substrate 101 can be prevented, as a result the epitaxial film can be more efficiently formed on the substrate 101.

In the film-forming method according to the present embodiment, when the period for stopping the supply of the source gas 137 is set by the gas control unit 140 in the above-mentioned example, the period for increasing the amount of the supply of the purge gas 151 can be set while the source gas 137 is stopping.

FIG. 3 is a diagram for explaining another example of the film-forming method according to the present embodiment.

In another example of the film-forming method according to the present embodiment, as seen in FIG. 3, the flow amount of the purge gas 151 supplied through the gas supply pipe 111 to the area P₂ changes depending on the time by the gas control unit 140.

That is, a plurality of periods of supplying the source gas 137 can be intermittently set by the gas control unit 140 in the process for forming the epitaxial film on the substrate 101 that has been heated. The period for temporarily stopping supplying the source gas 137 by the gas control unit 140 can be set between the periods of supplying of the source gas 137. The period that the purge gas 151 increases is the same length as the period for stopping supplying the source gas 137 or less than the length, while the source gas 137 is stopping, in another example of the film-forming method according to the present embodiment.

In this case, the substrate 101 can be rotated at high speed while being heated and while slightly vibrating up and down in the period for increasing the purge gas 151. Therefore the adhesion between the substrate 101 and the susceptor 102 can be prevented even if the thin film caused by the source gas 137 is formed between the substrate 101 and the susceptor 102.

The supply of the purge gas 151 will not be increased in the period of supplying the source gas 137, and the previous amount of the supply of the purge gas 151 will be maintained to control the slight vibration up and down of the substrate 101. Therefore, the adhesion between the substrate 101 and the susceptor 102 can be prevented and the epitaxial film having high quality can be more efficiently formed in more stable condition.

As the mentioned above, the supply of the purge gas 151 is stopped or decreased to a smaller amount when the cylindrical portion 104a for forming the area P₂ does not have the discharge portion 155, thereby the area P₂ is substantially separated from the area P₁. In that case, the period of supplying the purge gas 151 can be set while the supply of the source gas 137 is stopped, as other example of the film-forming method according to the present embodiment.

FIG. 4 is a diagram showing another example of the film-forming method according to the present embodiment.

FIG. 4 shows the example in which the gas control unit 140 intermittently sets the period of supplying the purge gas 151 to the area P₂, and the flow amount of the purge gas 151 supplied to the area P₂ changes depending on the time.

That is, in another example of the film-forming method according to the present embodiment, the gas control unit 140 in the process for forming the epitaxial film on the substrate 101, while the substrate is heated, can intermittently set a plurality of periods of supplying the source gas 137. The period for temporarily stopping supplying the source gas 137 can be set by the gas control unit 140 between the periods of supplying the source gas 137. The period for temporarily supplying the purge gas 151 to the area P₂ can be set for the same length as the period for stopping supplying the source gas 137 or less while the source gas 137 is stopping in the other example of the film-forming method according to the present embodiment.

In this case, the substrate 101 can be rotated at high speed while the substrate 101 is heated, and slightly vibrating up and down in the period of supplying the purge gas 151. Therefore the adhesion between the substrate 101 and the susceptor 102 can be prevented even if the thin film caused by the source gas 137 is formed between the substrate 101 and the susceptor 102.

The purge gas 151 will not be supplied in the period of supplying the source gas 137 to control the slight vibration up and down of the substrate 101. Therefore the adhesion of between the substrate 101 and the susceptor 102 can be prevented and the epitaxial film having high quality can be more efficiently formed in more stable condition according to another example of the film-forming method according to the present embodiment.

Features and advantages of the present invention can be summarized as follows.

According to the film-forming method of the present invention, the adhesion between a substrate, such as a wafer, and a unit for supporting the substrate, such as a susceptor, can be prevented. According to the film-forming apparatus of the present invention, the adhesion between a substrate such as a wafer and a unit for supporting the substrate such as a susceptor can be prevented.

The present invention is not limited to the embodiments described and can be implemented in various ways without departing from the spirit of the invention.

In addition to the above-mentioned embodiments, an epitaxial growth system cited as the example of a film-forming apparatus for forming epitaxial film in the present invention is not limited to these. Source gas supplied into the film-forming chamber for forming a film on the surface of a semiconductor substrate, while heating the semiconductor substrate, can also be applied to other apparatus such as CVD (Chemical Vapor Deposition) film-forming apparatus.

What is claimed is:

1. A film-forming method comprising:
placing a substrate on a substrate supporting portion in a film-forming chamber;
supplying a source gas into the film-forming chamber while the substrate is rotating on a cylindrical portion supporting the substrate supporting portion thereon;
supplying a purge gas into the cylindrical portion and forming a film on the substrate while at least a part of the substrate is risen on the substrate supporting portion by discharge of the purge gas from between the substrate and the substrate supporting portion.

2. The film-forming method according to claim 1, wherein the pressure of the cylindrical portion is higher than the pressure in the film-forming chamber.

3. The film-forming method according to claim 1, wherein the purge gas and the source gas are supplied at the same time.

4. The film-forming method according to claim 3, wherein the amount of purge gas is temporarily increased while the source gas is supplied, thereby at least a part of the substrate is risen on the substrate supporting portion.

5. The film-forming method according to claim 4, wherein a period of increasing the amount of purge gas is one continuous period.

6. The film-forming method according to claim 4, wherein a plurality of periods for increasing the amount the purge gas are intermittently set.

7. The film-forming method according to claim 4, wherein the amount of purge gas is temporarily increased to ten times or more.

8. The film-forming method according to claim 1, wherein the purge gas is supplied when the supply of the source gas is stopped, thereby at least a part of the substrate is risen on the substrate supporting portion.

9. The film-forming method according to claim 8, wherein a period of supplying purge gas is one continuous period.

10. The film-forming method according to claim 8, wherein supplying purge gas is performed in a plurality times.

11. The film-forming method according to claim 10, wherein the purge gas is supplied for the same period, or a smaller period, as the period for stopping supply of the source gas.

12. The film-forming method according to claim 8, wherein an amount of purge gas is temporarily increased, thereby at least a part of the substrate is risen on the substrate supporting portion.

13. The film-forming method according to claim 12, wherein the amount of purge gas is temporarily increased to ten times or more.

14. The film-forming method according to claim 1, wherein the purge gas is at least one selected in the group consisting of argon gas, helium gas hydrogen gas and nitrogen gas.

15. A film-forming apparatus comprising:
a film-forming chamber;
a source gas supply portion for supplying a source gas into the film-forming chamber;
a substrate supporting portion for holding a substrate in the film-forming chamber;
a rotating portion having a cylindrical portion for supporting the substrate supporting portion;
a purge gas supply portion for supplying the purge gas into the cylindrical portion; and
a control unit for controlling the supply of the source gas and the purge gas so that the purge gas is discharged from between the substrate and the substrate supporting portion, thereby at least a part of the substrate is risen on the substrate supporting portion.

16. The film-forming apparatus according to claim 15, wherein the substrate supporting portion includes a counterbore for positioning the substrate thereon; and
an overhanging portion provided at the upper portion of the counterbore and overhangs to the internal of the substrate supporting portion.

17. The film-forming apparatus according to claim 15, further comprising a discharge portion for discharging the purge gas from the cylindrical portion.
